(19) United States
(12) Patent Application Publication
(10) Pub. No.: US 2026/0182445 A1
(43) Pub. Date: Jun. 25, 2026

(54) PACKAGE STRUCTURE AND METHOD FOR FORMING SAME

(71) Applicant: JCET Advanced Packaging Co., LTD., Wuxi (CN)

(72) Inventors: Haijie CHEN, Wuxi, Jiangsu (CN); Jielei XIE, Wuxi, Jiangsu (CN); Jingyu WU, Wuxi, Jiangsu (CN)

(73) Assignee: JCET Advanced Packaging Co., LTD., Wuxi, JS (CN)

(21) Appl. No.: 18/729,624

(22) PCT Filed: Nov. 27, 2023
(86) PCT No.: PCT/CN2023/134258

§ 371 Date: Jul. 17, 2024

(30) Foreign Application Priority Data
Jun. 5, 2023 (CN) 202310659565.X

(51) Int. Cl. H10W 74/10; H10W 70/05; H10W 70/60; H10W 90/00; H10W 90/20; H10W 90/24

(52) U.S. Cl. CPC H10W 74/142; H10W 70/05; H10W 70/093; H10W 70/614; H10W 74/117; H10W 90/24; H10W 90/297; H10W 90/724

(57) ABSTRACT

A method for forming a package structure includes: providing an interposer, where the interposer includes first conductive pads, the first conductive pads being exposed on a first surface of the first interposer; providing a device substrate, where the device substrate includes a passive device layer and a first redistribution layer covering the passive device layer, the passive device layer including a passive device, and the first redistribution layer including a second conductive pads, wherein the second conductive pads is electrically connected to the passive device, and the second conductive pads is exposed on a first surface of the first redistribution layer; bonding the interposer to the device substrate by a hybrid bonding process using the first surface of the interposer and the first surface of the first redistribution layer as a bonding surface.

### CROSS-REFERENCE TO RELATED APPLICATION

This application is the U.S. national phase of International Application No. PCT/CN2023/134258, filed on Nov. 27, 2023, which is based upon and claims priority to Chinese Patent Application No. 202310659565.X, filed on Jun. 5, 2023, the entire disclosures of both of which are incorporated herein by reference for all purposes.

### TECHNICAL FIELD

The present disclosure relates to the technical field of semiconductor packaging, and in particular, relates to a package structure and a packaging method.

### BACKGROUND

With the continuous evolution of advanced packaging technologies, the chiplet technology based on the advanced packaging technology has become an important way to improve the design efficiency. The chiplet technology refers to a semiconductor manufacturing approach where integrable dies with specific functions are prefabricated separately and then the dies having different functions and manufactured at different process nodes are integrated into a single package or system by using the system-in-package (SiP) technology and by interconnection and packaging architecture between effective dies.

Currently, employing an adapter board is an effective way to achieve electrical interconnection between chips as well as between chips and substrates. However, the conventional interposer is not integrated with a passive device (for example, a capacitor). The passive device needs to be connected to the interposer by an additional process such as surface mount technology (SMT), which does not match the flip chip bonding process between the chips and between the chips and the substrates. In addition, the passive device typically has a large size, resulting in a waste of the area of the patch panel, which is not conducive to miniaturization of a package structure.

Therefore, how to realize packaging between the passive device and the interposer becomes the focus of research.

### SUMMARY

The technical problem to be solved by embodiments of the present disclosure is to provide a package structure and a method for forming the same, which improve the compatibility of a package process, and is conducive to miniaturization of the package structure.

In view of the above, a first aspect of the present disclosure provides a method for forming a package structure. The method includes: providing an interposer, wherein the interposer includes first conductive pads, the first conductive pads being exposed on the first surface of the first interposer; providing a device substrate, wherein the device substrate includes a passive device layer and a first redistribution layer covering the passive device layer, the passive device layer including a passive device, and the first redistribution layer including second conductive pads, wherein the second conductive pads are electrically connected to the passive device, and the second conductive pads are exposed on the first surface of the first redistribution layer; bonding the interposer to the device substrate by a hybrid bonding process using the first surface of the interposer and the first surface of the first redistribution layer as a bonding surface, wherein the first conductive pads are electrically connected to the second conductive pads; removing a portion of the device substrate from a surface, facing away from the interposer, of the device substrate to form a recess, wherein the recess exposes the interposer or the first redistribution layer, and a region, where the passive device is displayed, of the passive device layer is retained; forming a silicon bridge in the recess, wherein the silicon bridge includes third conductive pads; and mounting a functional chip on a side, facing away from the interposer, of the device substrate, wherein the functional chip is electrically connected to the third conductive pads.

A second aspect of the present disclosure further provides a package structure. The package structure includes: an interposer, including first conductive pads; a device substrate, including a passive device layer and a first redistribution layer covering the passive device layer, wherein the passive device layer includes a passive device, the first distribution layer is bonded to the interposer, and the first redistribution layer includes second conductive pads, one end of the second conductive pads being electrically connected to the passive device, and the other end of the second conductive pads being electrically connected to the first conductive pads, and wherein a recess is displayed in the device substrate, the recess exposing the interposer or the first redistribution layer; a silicon bridge, displayed in the recess, wherein the silicon bridge includes a third conductive pads; and a functional chip, displayed on a side, facing away from the interposer, of the device substrate, wherein the functional chip is electrically connected to the third conductive pads.

### BRIEF DESCRIPTION OF THE DRAWINGS

For clearer descriptions of the technical solutions according to the embodiments of the present disclosure, hereinafter brief description is given with reference to the accompanying drawings for illustrating the embodiments. Apparently, the accompanying drawings described hereinafter only illustrate some embodiments of the present disclosure, and other accompanying drawings may also be derived by persons of ordinary skill in the art based on these accompanying drawings without any creative effort.

FIG. 1 is a schematic flowchart of steps of a method for forming a package structure according to some embodiments of the present disclosure; and

FIG. 2A to FIG. 2J are schematic diagrams of main steps of a method for forming a package structure according to some embodiments of the present disclosure.

### DETAILED DESCRIPTION

Hereinafter, specific embodiments of a package structure and a method for forming the package structure according to the present disclosure are described in detail with reference to the accompanying drawings.

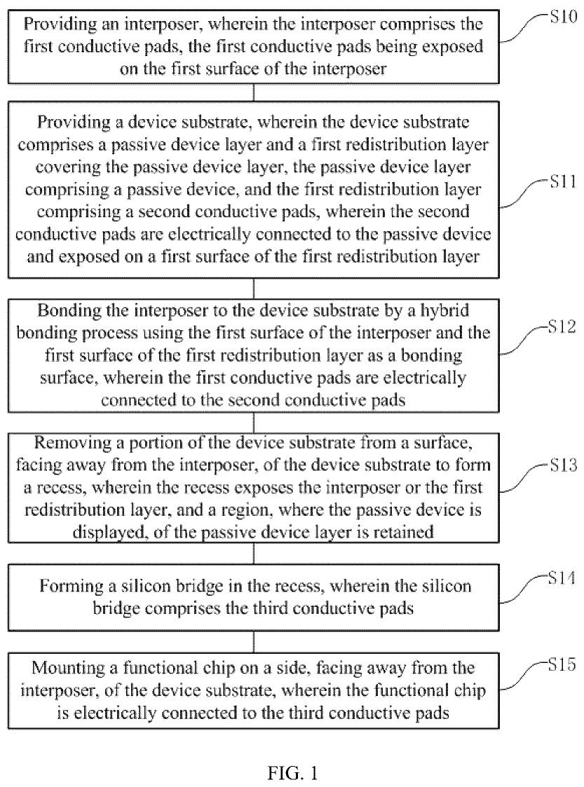

FIG. 1 is a schematic flowchart of steps of a method for forming a package structure according to some embodiments of the present disclosure. Referring to FIG. 1, the method includes: S10, providing an interposer, wherein the interposer includes a first conductive pads, the first conductive pads being exposed on a first surface of the first interposer; S11, providing a device substrate, wherein the device substrate includes a passive device layer and a first redistribution layer covering the passive device layer, the passive device layer including a passive device, and the first redistribution layer including a second conductive pads, wherein the second conductive pads is electrically connected to the passive device, and the second conductive pads is exposed on a first surface of the first redistribution layer; S12, bonding the interposer to the device substrate by a hybrid bonding process using the first surface of the interposer and the first surface of the first redistribution layer as a bonding surface, wherein the first conductive pads is electrically connected to the second conductive pads; S13, removing a portion of the device substrate from a surface, facing away from the interposer, of the device substrate to form a recess, wherein the recess exposes the interposer or the first redistribution layer, and a region, where the passive device is displayed, of the passive device layer is retained; S14, forming a silicon bridge in the recess, wherein the silicon bridge includes a third conductive pads; and S15, mounting a functional chip on a side, facing away from the interposer, of the device substrate, wherein the functional chip is electrically connected to the third conductive pads.

In the package structure according to the embodiments of the present disclosure, before the functional chip is displayed, a passive device is directly integrated inside the interposer by a wafer-level package process, and the silicon bridge is formed upon integration of the passive device, such that an adapter board constituted by the interposer and the silicon bridge is formed; and then the functional chip is electrically connected to the adapter board such that the package structure is eventually formed. In the method for forming the package structure according to the present disclosure, the passive device may be connected to the adapter board with no need of an additional SMT process, such that the compatibility of the process is greatly improved. Further, the area of the interposer is greatly reduced, which is conducive to the miniaturization of the package structure. The functional chip and the passive device are displayed on the same side of the interposer, such that the passive device is close to the functional chip, and the performance of the package structure is improved. In addition, during manufacture of the passive device in the device substrate, the parameters, for example, the capacitances of the capacitors, of the passive device may be adjusted, such that the passive device and the functional chip are precisely matched.

In some embodiments, the interposer further includes a fourth conductive pads, the fourth conductive pads being exposed on the first surface of the interposer; and the device substrate further includes a first conductive pillars, the first conductive pillars being displayed in the device substrate and a surface of the first conductive pillars being exposed on the first surface of the first redistribution layer, wherein in bonding the interposer to the device substrate by the hybrid bonding process, the fourth conductive pads is electrically connected to the first conductive pillars.

In some embodiments, upon forming the silicon bridge in the recess, the method further includes: sealing with plastic to form a package body, wherein the package body fills the recess, and the third conductive pads is exposed in the package body.

In some embodiments, sealing with the compound to form the package body includes: filling a compound, wherein the compound fills the recess, and the compound further covers the surface, facing away from the interposer, of the device substrate; and thinning the compound to remove the compound on the surface, facing away from the interposer, of the device substrate and expose the third conductive pads, wherein a remaining portion of the compound serves as the package body.

In some embodiments, upon sealing with the compound to form the package body, the method further includes: thinning the device substrate from the surface, facing away from the interposer, of the device substrate to expose a surface of the first conductive pillars.

In some embodiments, upon thinning the device substrate from the surface, facing away from the interposer, of the device substrate, the method further includes: planarizing the surface, facing away from the interposer, of the device substrate, a surface of the package body, and a surface of the silicon bridge.

In some embodiments, upon forming the silicon bridge in the recess, the method further includes: forming a second redistribution layer, wherein the second redistribution layer covers the surface, facing away from the interposer, of the device substrate and a surface of the silicon bridge, and the second redistribution layer includes a fifth conductive pads, the fifth conductive pads being electrically connected to the third conductive pads, and the fifth conductive pads being exposed on a surface of the second redistribution layer; wherein in mounting the functional chip on the side, facing away from the interposer, of the device substrate, the functional chip is further electrically connected to the seventh conductive pads.

In some embodiments, the second redistribution layer further includes a seventh conductive pads, wherein one end of the seventh conductive pads is electrically connected to the first conductive pillars, and the seventh conductive pads is exposed on the surface of the second redistribution layer; wherein in mounting the functional chip on the side, facing away from the interposer, of the device substrate, the functional chip is further electrically connected to the seventh conductive pads.

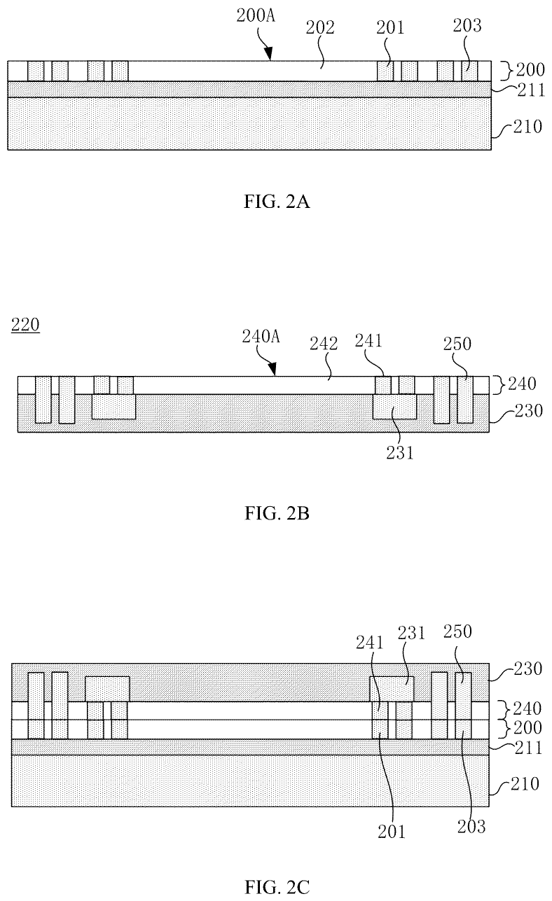

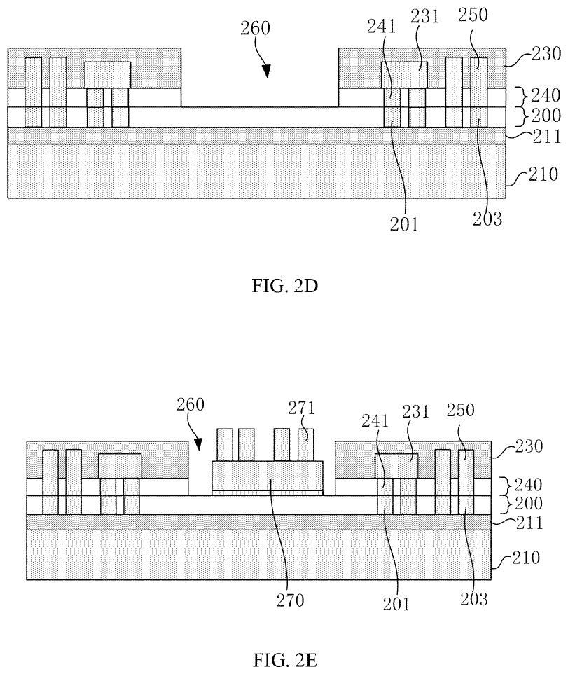

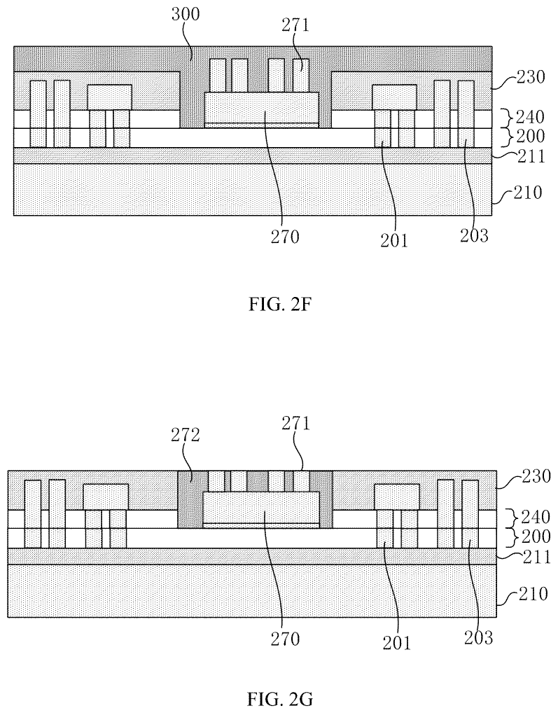

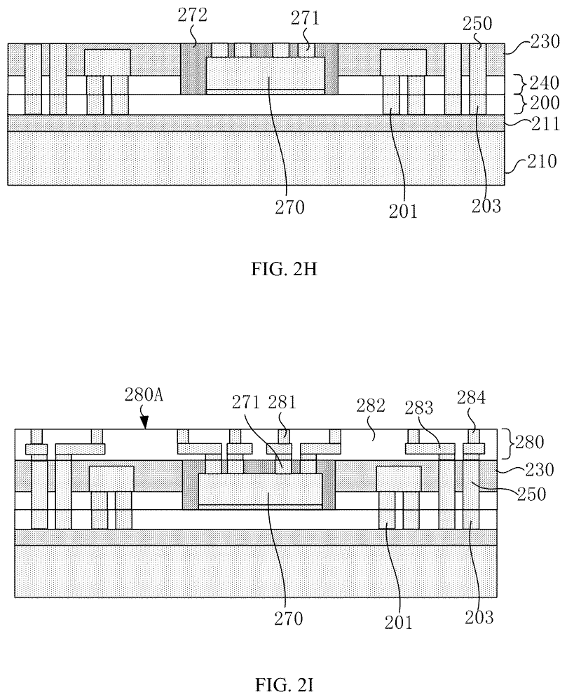

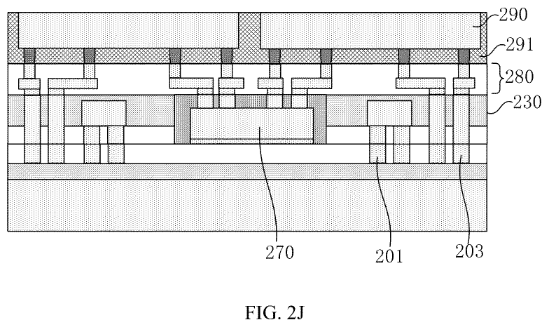

FIG. 2A to FIG. 2J are schematic diagrams of main steps of a method for forming a package structure according to some embodiments of the present disclosure.

Referring to FIG. 1 and FIG. 2A, in S10, an interposer 200 is provided. The interposer 200 includes a first conductive pads 201. The first conductive pads 201 are exposed on a first surface 200A of the first interposer 200.

In some embodiments, the interposer 200 further includes a first dielectric layer 202. The first conductive pads 201 are formed in the first dielectric layer 202, and are exposed on a top surface of the first dielectric layer 202. The top surface serves as the first surface 200A of the interposer 200. The first dielectric layer 202 includes, but is not limited to, an organic dielectric layer. The organic dielectric layer may be made of an organic resin. The organic resin includes, but is not limited to, an epoxy resin (FR4), a bismaleimide-triazine (BT) resin, polyphenylene ether (PPE) resin, or a polyimide (PI) resin.

In some embodiments, the first conductive pads 201 may be metal pads. For example, in some embodiments, the first conductive pads 201 are a copper pads.

In some embodiments, the first conductive pads 201 may extend through the first dielectric layer 202. That is, an upper surface and a lower surface of the first conductive pads 201 are respectively exposed on the top surface and a bottom surface of the first dielectric layer 202. In some other embodiments, the interposer 200 further includes conductive interconnect wires and at least one bottom conductive pads. The conductive interconnect wire are displayed in the first dielectric layer 202, and the first conductive pads 201 are electrically connected to the conductive interconnect wires. The bottom conductive pads are displayed at a bottom of the first dielectric layer 202, and the bottom conductive pads are electrically connected to the conductive interconnect wires, that is, the first conductive pads 201 are electrically connected to the bottom conductive pads via the conductive interconnect wires. A surface of the bottom conductive pads are exposed on the bottom surface of the first dielectric layer 202, and is configured to serve as an external connection region of the bottom of the interposer 200.

In some embodiments, the interposer 200 further includes a fourth conductive pads 203. The fourth conductive pads 203 are exposed on the first surface 200A of the interposer 200. Specifically, in some embodiments, the fourth conductive pads 203 are formed in the first dielectric layer 202 and extends through the first dielectric layer 202. That is, an upper surface and a lower surface of the fourth conductive pads 203 are respectively exposed on the top surface and the bottom surface of the first dielectric layer 202. In some other embodiments, an upper surface of the fourth conductive pads 203 are exposed on the top surface of the first dielectric layer 202, and the lower surface of the fourth conductive pads 203 are further electrically connected to the bottom conductive pads via the conductive interconnect wires.

As an example, some embodiments of the present disclosure provide a method for forming the interposer 200. The method includes: providing a carrier substrate 210; forming a sacrificial layer 211 on the carrier substrate 210; forming a first dielectric layer 202 on the sacrificial layer 211, wherein a via is defined in the first dielectric layer 202; and filling conductive material into the via to form the first conductive the pads 201 and fourth conductive pads 203. The first conductive pads 201 and the fourth conductive pads 203 are made of the same material and have the same structure, and are formed in the same step.

In some embodiments, the method further includes: planarizing the interposer 200. That is, prior to a hybrid bonding process, the first surface 200A of the interposer 200 is planarized, such that bonding strength of a package structure formed by a subsequent bonding process is enhanced. The planarization includes, but is not limited to, chemical mechanical polishing (CMP). In some embodiments, in forming the interposer 200, the conductive material is not only filled into the via, but also covers a portion of a surface of the first dielectric layer 202. In this case, during the planarization, the conductive material on the surface of the first dielectric layer 202 is removed.

Referring to FIG. 1 and FIG. 2B, in S11, providing a device substrate 220. The device substrate 220 includes a passive device layer 230 and a first redistribution layer 240 covering the passive device layer 230. The passive device layer 230 includes a passive device 231, and the first redistribution layer 240 includes a second conductive pads 241. The second conductive pads 241 is electrically connected to the passive device 231, and the second conductive pads 241 is exposed on a first surface 240A of the first redistribution layer 240.

The passive device 231 includes, but is not limited to, a resistor, a capacitor, or an inductor. For example, in some embodiments, the passive device 231 is a capacitor, and the passive device layer 230 is a capacitor layer, which may be obtained by preparing a capacitor on a wafer by a semiconductor process. The capacitor includes, but is not limited to, a trench capacitor.

The second conductive pads 241 are electrically connected to the passive device 231, and serves as a pin of the passive device 231. For example, in some embodiments, the passive device 231 is a capacitor, and the second conductive pads 241 are electrically connected to a positive electrode or a negative electrode of the capacitor, and serves as a pin of the positive electrode or the negative electrode of the capacitor.

In some embodiments, the first redistribution layer 240 includes a second dielectric layer 242. The second dielectric layer 242 covers the passive device layer 230, and the second conductive pads 241 extend through the second dielectric layer 242. One surface of the second conductive pads 241 are connected to the passive device 231, and the other surface of the second conductive pads 241 are exposed on a top surface of the second dielectric layer 242. The top surface serves as the first surface 240A of the first redistribution layer 240.

In some embodiments, the second dielectric layer 242 is an organic dielectric layer. The organic dielectric layer may be made of an organic resin. The organic resin includes, but is not limited to, an epoxy resin (FR4), a bismaleimide-triazine (BT) resin, polyphenylene ether (PPE) resin, or a polyimide (PI) resin. In some embodiments, the first dielectric layer 202 and the second dielectric 242 are layers made of the same material, and in this case, in the subsequent bonding process, the first dielectric layer 202 and the second dielectric layer 242 are bonded more securely.

In some embodiments, the first conductive pads 201 and the fourth conductive pads 241 may be both metal pads, and may be made of the same material or different materials. For example, in some embodiments, the first conductive pads 201 and the second conductive pads 241 are made of the same material, and are both copper pads. In this case, in the subsequent bonding process, a higher bonding strength is achieved between the first conductive pads 201 and the second conductive pads 241.

In some embodiments, the second conductive pads 241 extend through the second dielectric layer 242. In some other embodiments, the second conductive pads 241 are only disposed in a portion of a region under the top surface of the second dielectric layer 242, and are electrically led out from a bottom surface of the second dielectric layer 242 via conductive interconnect wires in the second dielectric layer 242. That is, the second conductive pads 241 are electrically connected to the passive device 231 via the conductive interconnect wires.

In the method for forming the interposer according to the embodiments of the present disclosure, during manufacture of the passive device 231 in the device substrate 220, parameters of the passive device 231 may be adjusted, for example, capacitances of capacitors may be adjusted by changing the manufacture process and adjusting a capacitance matrix area, such that the parameters of the passive device approach calculated values in simulation design, and precise matching between the passive device 231 and a subsequently displayed functional chip 290 is achieved.

In some embodiments, the device substrate 220 further includes a first conductive pillars 250. The first conductive pillars 250 are displayed in the device substrate 220. One surface of the first conductive pillars 250 are exposed on the first surface 240A of the first redistribution layer 240, and the other surface of the first conductive pillars 250 are not exposed. Specifically, in some embodiments, the first conductive pillars 250 extend from the second dielectric layer 242 into the device substrate 220 along a direction perpendicular to the second dielectric layer 242, and one surface of the first conductive pillars 250 are exposed on the top surface of the second dielectric layer 242, and the other surface of the first conductive pillars 250 are disposed in the device substrate 220 and is not exposed.

As an example, some embodiments of the present disclosure provide a method for forming the device substrate 220. The method includes: providing a wafer, wherein the wafer includes a passive device layer 230, and a first redistribution layer 240 is formed on a surface of the passive device layer 230; and forming the first conductive pillars 250, wherein the first conductive pillars 250 extends from a first surface 240A of the first redistribution layer 240 into the passive device layer 230. The method for forming the first conductive pillars 250 includes, but is not limited to, the through silicon vias (TSV) technology.

In some embodiments, the method further includes: planarizing the device substrate 220. That is, prior to a hybrid bonding process, the first surface 240A of the first redistribution layer 240 is planarized, such that bonding strength of a package structure formed by a subsequent bonding process is enhanced. The planarization includes, but is not limited to, chemical mechanical polishing (CMP).

Referring to FIG. 1 and FIG. 2C, in S12, the interposer 200 is bonded to the device substrate 220 by a hybrid bonding process using the first surface 200A of the interposer 200 and the first surface 240A of the first redistribution layer 240 as a bonding surface, wherein the first conductive pads 201 are electrically connected to the second conductive pads 241. The structure formed by the hybrid bonding process has a higher current carrying capacity and a better thermal performance. In some embodiments, the top surface of the first dielectric layer 202 is also bonded to the top surface of the second dielectric layer 242. In some embodiments, in this step, the fourth conductive pads 203 are electrically connected to the first conductive pillars 250.

The hybrid bonding process includes: attaching the first surface 200A of the interposer 200 onto the first surface 240A of the first redistribution layer 240, wherein the first dielectric layer 202 is bonded to the second dielectric layer 242; and performing annealing, such that the first conductive pads 201 are bonded to the second conductive pads 241 such that a bonding structure is formed.

In some embodiments, prior to the bonding process, activation treatment is performed for the first surface 200A of the interposer 200 and/or the first surface 240A of the first redistribution layer 240, such that an activation site is formed on the first surface 200A of the interposer 200 and/or the first surface 240A of the first redistribution layer 240. In this way, the strength of bonding between the interposer 200 and the first redistribution layer 240 is enhanced. The activation process includes, but is not limited to, plasma activation treatment. Specifically, prior to the bonding process, activation treatment is performed for the first surface 200A of the interposer 200 and/or the first surface 240A of the first redistribution layer 240, such that an activation site is formed on the surface of the first dielectric layer 202 and/or the second dielectric layer 242. In this way, the strength of bonding between the first dielectric layer 202 and the second dielectric layer 242 is enhanced.

In some embodiments, prior to the bonding process, activation treatment is performed for the first surface 200A of the interposer 200 and the first surface 240A of the first redistribution layer 240. In some other embodiments, prior to the bonding process, activation treatment is performed for one of the first surface 200A of the interposer 200 and the first surface 240A of the first redistribution layer 240.

Referring to FIG. 1 and FIG. 2D, in S13, a portion of the device substrate 220 is removed from a surface, facing away from the interposer 200, of the device substrate 220 to form a recess 260. The recess 260 exposes the interposer 200 or the first redistribution layer 240, and a region, where the passive device 231 is displayed, of the passive device layer 230 is retained.

In this step, the region, where the passive device 231 is displayed, of the passive device layer 230 is retained, and the region, where the passive device 231 is not displayed, is removed. Upon removal of the region of the passive device layer 230, the first redistribution layer 240 corresponding to the removed region of the passive device layer 230 is also removed, such that the interposer 200 is exposed. The recess 260 uses the device substrate 220 as a side wall, and uses the interposer 200 as a bottom surface. In some other embodiments, a portion of the passive device layer 230 may be only removed, whereas the first redistribution layer 240 is not removed, or a portion of the first redistribution layer 240 is removed.

The method for removing the region of the passive device layer 230 includes, but is not limited to, an etching process. For example, in some embodiments, the method for removing the region of the passive device layer 230 includes: forming a patterned mask layer on the surface, facing away from the interposer 200, of the device substrate 220, wherein the mask layer shields a region, where the passive device 231 is displayed, of the passive device layer 230, and exposes a region, where the passive device 231 is not displayed, of the passive device layer 230; etching the passive device layer 230 and the first redistribution layer 240 using the mask layer as a mask before the interposer is exposed; and removing the mask layer.

Referring to FIG. 1 and FIG. 2E, in S14, a silicon bridge 270 is formed in the recess 260. The silicon bridge 270 includes third conductive pads 271. An interconnect wire is displayed in the silicon bridge 270, such that in the subsequently formed package structure, the functional chip 290 is capable of achieving electrical connection between chips or electrical connection thereof via the third conductive pads 271 and the interconnect structure. In this step, the silicon bridge 270 is attached onto the surface of the interposer 200 by a mounting process. The third conductive pads 271 includes, but is not limited to, copper pads.

In this step, the recess 260 achieves effects of limiting and alignment, such that neither an additional recess for mounting the silicon bridge 270 needs to be formed in the interposer 200, nor a precise alignment process is required. In this way, the process difficulty is lowered.

In some embodiments, the body of the silicon bridge 270 is attached onto the surface of the interposer 200, and the top surface of the third conductive pads 271 protrudes from the body of the silicon bridge 270 and protrudes from the surface of the device substrate 220. In some other embodiments, the body of the silicon bridge 270 is attached onto the surface of the interposer 200, and the top surface of the third conductive pads 271 protrudes from the body of the silicon bridge 270 and is lower than the surface of the device substrate 220 or flush with the surface of the device substrate 220.

In some embodiments, upon forming the silicon bridge 270 in the recess 260, the method further includes: referring to FIG. 2G, to form a package body 272, wherein the package body 272 fills the recess 260, and the third conductive pads 271 are exposed in the package body 272. The package body 272 is capable of protecting and sealing the silicon bridge 270.

Specifically, in some embodiments, sealing with plastic to form the package body 272 includes: referring to FIG. 2F, filling a compound 300, wherein the compound 300 fills the recess 260, and the compound 300 further covers the surface, facing away from the interposer 200, of the device substrate 220. In this step, the compound 300 further covers a top surface of the third conductive pads 271. Referring to FIG. 2G, the compound 300 is thinned to remove the compound 300 on the surface, facing away from the interposer 200, of the device substrate 220 and expose the third conductive pads 271, wherein a remaining portion of the compound 300 serves as the package body 272. In this step, in the case that the top surface of the third conductive pads 271 protrudes from the surface of the device substrate 220, during thinning the package body 300, the third conductive pads 271 are thinned meanwhile.

Referring to FIG. 2H, in some embodiments, upon sealing with plastic to form the package body 272, the method further includes: thinning the device substrate 220 from the surface, facing away from the interposer 200, of the device substrate 220 to expose a surface of the first conductive pillars 250. In this step, the device substrate 220 may be thinned by a chemical mechanical polishing (CMP) process or a mechanical polishing process.

In some embodiments, upon thinning the device substrate 220 from the surface, facing away from the interposer 200, of the device substrate 220, the method includes: planarizing the surface, facing away from the interposer 200, of the device substrate 220, a surface of the package body 272, and a surface of the silicon bridge 270, to provide a flat surface for subsequently forming other structures. The planarization includes, but is not limited to, a CMP process.

Referring to FIG. 2I, in some embodiments, upon forming the silicon bridge 270 in the recess 260, the method further includes: forming a second redistribution layer 280. The second redistribution layer 280 covers the surface, facing away from the interposer 200, of the device substrate 220 and a surface of the silicon bridge 270. The second redistribution layer 280 includes the fifth conductive pads 281. The fifth conductive pads 281 are electrically connected to the third conductive pads 271, and the fifth conductive pads 281 are exposed on a surface 280A of the second redistribution layer 280. In some embodiments, the package body 272 covers the surface of the surface of the silicon bridge 270, and the second redistribution layer 280 further covers a surface of the package body 272. The fifth conductive pads 281 may be a metal pads, for example, copper pads.

In some embodiments, the second redistribution layer 280 further includes a third dielectric layer 282. The fifth conductive pads 281 are formed in the third dielectric layer 282, and is exposed on a top surface of the third dielectric layer 282. The top surface serves as the first surface 280A of the second redistribution layer 280. The third dielectric layer 282 includes, but is not limited to, an organic dielectric layer. The organic dielectric layer may be made of an organic resin. The organic resin includes, but is not limited to, an epoxy resin (FR4), a bismaleimide-triazine (BT) resin, polyphenylene ether (PPE) resin, or a polyimide (PI) resin.

In some embodiments, the fifth conductive pads 281 may extend through the third dielectric layer 282. That is, an upper surface and a lower surface of the fifth conductive pads 281 are respectively exposed on the top surface and a bottom surface of the third dielectric layer 282. In some other embodiments, the second redistribution layer 280 further includes conductive interconnect wires 283. The conductive interconnect wires 283 are displayed in the third dielectric layer 282, and the fifth conductive pads 281 are electrically connected to one end of the conductive interconnect wires 283, and the other end of the conductive interconnect wires 283 are electrically connected to the third conductive pillars 271. That is, the fifth conductive pads 281 are electrically connected to the third conductive pads 271 via the conductive interconnect wires 283.

In some embodiments, the second redistribution layer 280 further includes a seventh conductive pads 284. One end of the seventh conductive pads 284 are electrically connected to the first conductive pillars 250, and the seventh conductive pads 284 are exposed on the surface of the second redistribution layer 280. The seventh conductive pads 284 may be metal pads, for example, copper pads. In some embodiments, the seventh conductive pads 284 may extend through the third dielectric layer 282. That is, an upper surface and a lower surface of the seventh conductive pads 284 are respectively exposed on the top surface and the bottom surface of the third dielectric layer 282. In some other embodiments, the seventh conductive pads 284 are electrically connected to one end of the conductive interconnect wires 283, and the other end of the conductive interconnect wires 283 are electrically connected to the first conductive pillars 250. That is, the seventh conductive pads 284 are electrically connected to the first conductive pillars 250 via the conductive interconnect wires 283.

In this step, in the step of forming the second redistribution layer 280, the conductive interconnect wires 283, the fifth conductive pads 281, and the seventh conductive pads 284 may be formed by performing the redistribution process for multiple times.

Referring to FIG. 1 and FIG. 2J, in S15, a functional chip 290 is mounted on the side, facing away from the interposer 200, of the device substrate 220. The functional chip 290 is electrically connected to the third functional chip 271, and hence the package structure is formed.

In the package structure, the function chip 290 and the passive device 231 are displayed on the same side of the interposer 200, such that the passive device 231 is close to the functional chip 290, and hence the performance of the package structure is enhanced.

In some embodiments, the functional chip 290 is displayed on the first surface 280A of the second redistribution layer 280, and is electrically connected to the fifth conductive pads 281 and electrically connected to the third conductive pads 271 via the fifth conductive pads 281. Further, the functional chip 290 is further electrically connected to the seventh conductive pads 284, and is electrically connected to the first conductive pillars 250 via the seventh conductive pads 284.

One or more functional chips 290 may be displayed, which are all displayed on the first surface of the second redistribution layer 280. The conductive pads on a side, facing towards the device substrate 220, of the functional chip 290 are electrically connected to the fifth conductive pads 281 and the seventh conductive pads 284. In some embodiments, the functional chip 290 may be electrically connected to the fifth conductive pads 281 and the seventh conductive pads 284 by a flip chip bonding process. It may be understood that conductive pads of different functional chips 290 may be electrically connected via the silicon bridge 270. The conductive pads of the functional chip 290 may be electrically connected to the interposer 200 via the first conductive pillars250.

In some embodiments, upon mounting the functional chip 290, the method further includes: forming a plastic package structure 291. The plastic package structure 291 wraps the functional chip 290, and is filled into a gap between the functional chip 290 and the second redistribution layer 280, to seal and support the functional chip 290.

With the method for forming the package structure according to the present disclosure, there is no need to connect the passive device 231 and the interposer by an additional SMT process, such that the compatibility of the process is greatly improved. Further, the method greatly reduces the area of the interposer 200 and is conducive to the miniaturization of the package structure. In addition, during manufacture of the passive device 231 in the device substrate 220, the parameters, for example, the capacitances of the capacitors, of the passive device 231 may be adjusted, such that the passive device 231 and the functional chip 290 are precisely matched.

In the method for forming the package structure according to the embodiments of the present disclosure, before the functional chip is displayed, a passive device is directly integrated inside the interposer by a wafer-level package process, and the silicon bridge is formed upon integration of the passive device, such that an interposer constituted by the interposer and the silicon bridge is formed; and then the functional chip is electrically connected to the interposer such that the package structure is eventually formed. In the method for forming the package structure according to the present disclosure, the passive device may be connected to the interposer with no need of an additional SMT process, such that the compatibility of the process is greatly improved. Further, the area of the interposer is greatly reduced, which is conducive to the miniaturization of the package structure. The functional chip and the passive device are displayed on the same side of the interposer, such that the passive device is close to the functional chip, and the performance of the package structure is improved. In addition, during manufacture of the passive device in the device substrate, the parameters, for example, the capacitances of the capacitors, of the passive device may be adjusted, such that the passive device and the functional chip are precisely matched.

Some embodiments of the present disclosure further provide a package structure that is formed using the method for forming the package structure as described above.

Referring to FIG. 2A to FIG. 2J, the package structure includes: an interposer 200, including a first conductive pads 201; a device substrate 220, including a passive device layer 230 and a first redistribution layer 240 covering the passive device layer 230, wherein the passive device layer 230 includes a passive device 231, the first distribution layer 240 is bonded to the interposer 200, and the first redistribution layer 240 includes a second conductive pads 241, one end of the second conductive pads 241 being electrically connected to the passive device 231, and the other end of the second conductive pads 241 being electrically connected to the first conductive pads 201, and wherein a recess 260 is displayed in the device substrate 220, the recess 260 exposing the interposer 200; a silicon bridge 270, displayed in the recess 260, wherein the silicon bridge 270 includes a third conductive pads 271; and a functional chip 290, displayed on a side, facing away from the interposer 200, of the device substrate 220, wherein the functional chip 290 is electrically connected to the third conductive pads 271.

In some embodiments, the interposer further includes a fourth conductive pads, and the device substrate further includes a first conductive pillars, wherein the first conductive pillars extends through the device substrate, and the fourth conductive pads are electrically connected to the first conductive pillars.

In some embodiments, the package structure further includes a second redistribution layer, wherein the second redistribution layer covers a surface, facing away from the interposer, of the device substrate and a surface of the silicon bridge, the functional chip is displayed on the second redistribution layer, and the second redistribution layer includes a fifth conductive pads, one end of the fifth conductive pads being electrically connected to the third conductive pads, and the other end of the fifth conductive pads being electrically connected to the functional chip.

In some embodiments, the second redistribution layer further includes a seventh conductive pads, wherein one end of the seventh conductive pads are electrically connected to the first conductive pillars, and the other end of the seventh conductive pads are electrically connected to the functional chip.

In some embodiments, the package structure further includes a package body, wherein the package body fills the recess.

In the package structure according to the embodiments of the present disclosure, the interposer 200 and the silicon bridge 270 form an interposer, and the passive device 231 is integrated in the interposer, such that the area of the interposer is greatly reduced, which is conducive to miniaturization of the package structure. The functional chip 290 and the passive device 231 are displayed on the same side of the interposer, such that the passive device 231 is close to the functional chip 290, and hence the performance of the package structure is enhanced. In addition, the passive device 231 and the chip 290 are precisely matched.

In some embodiments, the interposer 200 further includes a first dielectric layer 202. The first conductive pads 201 are formed in the first dielectric layer 202. The first dielectric layer 202 includes, but is not limited to, an organic dielectric layer. The first conductive pads 201 may be metal pads. For example, in some embodiment, the first conductive pads 201 are copper pads.

In some embodiment, the first conductive pads 201 may extend through the first dielectric layer 202. In some other embodiments, the interposer 200 further includes conductive interconnect wires and at least one bottom conductive pads. The conductive interconnect wires are displayed in the first dielectric layer 202, and the first conductive pads 201 are electrically connected to the conductive interconnect wires. The bottom conductive pads are displayed at a bottom of the first dielectric layer 202, and the bottom conductive pads are electrically connected to the conductive interconnect wires, that is, the first conductive pads 201 are electrically connected to the bottom conductive pads via the conductive interconnect wires, and the bottom conductive pads serves as an external connection region at the bottom of the interposer 200.

The passive device 231 includes, but is not limited to, a resistor, a capacitor, or an inductor. For example, in some embodiments, the passive device 231 is a capacitor, and the passive device layer 230 is a capacitor layer, wherein the capacitor includes, but is not limited to a deep trench capacitor. The second conductive pads 241 are electrically connected to the passive device 231, and serves as a pin of the passive device 231.

The first redistribution layer 240 is displayed between the interposer 200 and the passive device layer 230. In some embodiments, the first redistribution layer 240 includes a second dielectric layer 242. The second dielectric layer 242 is displayed between the interposer 200 and the passive device layer 230, and the second conductive pads 241 extends through the second dielectric layer 242. In some other embodiments, the second conductive pads 241 only disposed in a portion of a region under the top surface of the second dielectric layer 242, and is electrically led out from a bottom surface of the second dielectric layer 242 via conductive interconnect wires in the second dielectric layer 242. That is, the second conductive pads 241 are electrically connected to the passive device 231 via the conductive interconnect wires.

In some embodiments, the second dielectric layer 242 is an organic dielectric layer, and the second conductive pads 241 are a metal pads. In some embodiments, the first dielectric layer 202 and the second dielectric 242 are layers made of the same material, and the first conductive pads 201 and the second conductive pads 241 are made of the same material, such that a bonding strength between the first redistribution layer 240 and the interposer 200 is enhanced.

In some embodiments, the interposer 200 further includes the fourth conductive pads 203, and the device substrate 220 further includes a first conductive pillars 250, wherein the first conductive pillars 250 extends through the device substrate 220, and the fourth conductive pads 203 are electrically connected to the first conductive pillars 250.

In some embodiments, the recess 260 uses the device substrate 220 as a side wall, and uses the interposer 200 as a bottom surface. In some other embodiments, the recess 260 uses the device substrate 220 as a side wall, and uses the first redistribution layer 240 as a bottom surface. The silicon bridge 270 is displayed on the surface of the interposer 200 or the first redistribution layer 240.

In some embodiments, the package structure further includes a package body 272. The package body 272 fills the recess 260, and covers the silicon bridge 270 to protect and seal the silicon bridge 270. The package body 272 further wraps a side surface of the third conductive pads 271 to support and protect the third conductive pads 271.

In some embodiments, the package structure further includes a second redistribution layer 280. The second redistribution layer 280 covers a surface, facing away from the interposer 200, of the device substrate 220 and a surface of the silicon bridge 270. The functional chip 290 is displayed on the second redistribution layer 280. The second redistribution layer 280 includes a fifth conductive pads 281. One end of the fifth conductive pads 281 are electrically connected to the third conductive pads 271, and the other end of the fifth conductive pads 281 are electrically connected to the functional chip 290. In some embodiments, the second redistribution layer 280 further includes a seventh conductive pads 284. One end of the seventh conductive pads 284 are electrically connected to the first conductive pillars 250, and the other end of the seventh conductive pads 284 are electrically connected to the functional chip 290.

One or more functional chips 290 may be displayed. Conductive pads of different functional chips 290 may be electrically connected via the silicon bridge 270. The conductive pads of the functional chip 290 may be electrically connected to the interposer 200 via the first conductive pillars 250.

In some embodiments, the package structure further includes a plastic package structure 291. The plastic package structure 291 wraps the functional chip 290, and is filled into a gap between the functional chip 290 and the second redistribution layer 280, to seal and support the functional chip 290.

In the package structure according to the embodiments of the present disclosure, the area of the adapter board is greatly reduced, which is conducive to miniaturization of the package structure. In addition, the passive device 231 is close to the functional chip 290, and hence the performance of the package structure is enhanced. In addition, the passive device 231 and the chip 290 are precisely matched.

In addition, terms “comprise,” “include,” and variations thereof used herein in the text of the present disclosure are intended to define a non-exclusive meaning. It should be noted that the terms such as “first,” “second,” and the like in the specifications, claims and the accompanying drawings of the present disclosure are intended to distinguish different objects but are not intended to define a specific order or a definite time sequence. Unless otherwise clearly indicated in the context, it should be understood that the data used in this way can be interchanged under appropriate circumstances. The term “one or more” may be used to describe a feature, structure, or characteristic in the singular, or may be used to describe a feature, structure, or combination of features in the plural, depending at least in part on the context. The term “based on” may be understood as not necessarily intended to express a set of exclusive factors, but may alternatively allow for the presence of other factors not necessarily explicitly described, again depending at least in part on the context. In cases of no conflict, the embodiments and features in the embodiments of the present disclosure may be combined together. Further, in the above description, descriptions of well-known components and techniques are omitted so as not to unnecessarily obscure the inventive concepts of the present disclosure. In various embodiments of the present disclosure, the same or similar parts between the embodiments may be referenced to each other. In each embodiment, the portion that is different from other embodiments is concentrated and described.

Described above are preferred embodiments of the present disclosure. It should be noted that persons of ordinary skill in the art may derive other improvements or polishings without departing from the principles of the present disclosure. Such improvements and polishings shall be deemed as falling within the protection scope of the present disclosure.

1. A method for forming a package structure, comprising:
providing an interposer, wherein the interposer comprises a first conductive pads, the first conductive pads being exposed on the first surface of the interposer;
providing a device substrate, wherein the device substrate comprises a passive device layer and a first redistribution layer covering the passive device layer, the passive device layer comprising a passive device, and the first redistribution layer comprising second conductive pads, wherein the second conductive pads are electrically connected to the passive device, and exposed on a first surface of the first redistribution layer;
bonding the interposer to the device substrate by a hybrid bonding process using the first surface of the interposer and the first surface of the first redistribution layer as a bonding surface, wherein the first conductive pads are electrically connected to the second conductive pads;
removing a portion of the device substrate from a surface, facing away from the interposer, of the device substrate to form a recess, wherein the recess exposes the interposer or the first redistribution layer, and a region, where the passive device is displayed, of the passive device layer is retained;
forming a silicon bridge in the recess, wherein the silicon bridge comprises third conductive pads; and
mounting a functional chip on a side, facing away from the interposer, of the device substrate, wherein the functional chip is electrically connected to the third conductive pads.

2. The method according to claim 1, wherein the interposer further comprises a fourth conductive pads, the fourth conductive pads being exposed on the first surface of the interposer; and the device substrate further comprises a first conductive pillars, the first conductive pillars being displayed in the device substrate and a surface of the first conductive pillars being exposed on the first surface of the first redistribution layer;
and wherein bonding the interposer to the device substrate by the hybrid bonding process comprises electrically connecting the fourth conductive pads to the first conductive pillars.

3. The method according to claim 2, wherein upon forming the silicon bridge in the recess, the method further comprises: sealing with compound to form a package body, wherein the package body fills the recess, and the third conductive pads are exposed in the package body.

4. The method according to claim 3, wherein sealing with the compound to form the package body comprises:
filling a compound, wherein the compound fills the recess, and the compound further covers the surface, facing away from the interposer, of the device substrate; and
thinning the compound to remove the compound on the surface, facing away from the interposer, of the device substrate and exposing the third conductive pads, wherein a remaining portion of the compound serves as the package body.

5. The method according to claim 3, wherein upon sealing with compound to form the package body, the method further comprises: thinning the device substrate from the surface, facing away from the interposer, of the device substrate to expose a surface of the first conductive pillars.

6. The method according to claim 5, wherein upon thinning the device substrate from the surface, facing away from the interposer, of the device substrate, the method further comprises: planarizing the surface, facing away from the interposer, of the device substrate, a surface of the package body, and a surface of the silicon bridge.

7. The method according to claim 2, wherein upon forming the silicon bridge in the recess, the method further comprises: forming a second redistribution layer, wherein the second redistribution layer covers the surface, facing away from the interposer, of the device substrate and a surface of the silicon bridge, and the second redistribution layer comprises a fifth conductive pads, the fifth conductive pads being electrically connected to the third conductive pads, and the fifth conductive pads being exposed on a surface of the second redistribution layer;
and wherein mounting the functional chip on the side, facing away from the interposer, of the device substrate; comprises electrically connecting the functional chip to the fifth conductive pads.

8. The method according to claim 7, wherein the second redistribution layer further comprises seventh conductive pads, wherein one end of the seventh conductive pads are electrically connected to the first conductive pillars, and the seventh conductive pads are exposed on the surface of the second redistribution layer;
and wherein mounting the functional chip on the side, facing away from the interposer, of the device substrate further comprises: further electrically connecting the functional chip to the seventh conductive pads.

9. A package structure, comprising:
an interposer, comprising first conductive pads;
a device substrate, comprising a passive device layer and a first redistribution layer covering the passive device layer, wherein the passive device layer comprises a passive device, the first distribution layer is bonded to the interposer, and the first redistribution layer comprises second conductive pads, one end of the second conductive pads being electrically connected to the passive device, and the other end of the second conductive pads being electrically connected to the first conductive pads, and wherein a recess is displayed in the device substrate, the recess exposing the interposer or the first redistribution layer;
a silicon bridge, displayed in the recess, wherein the silicon bridge comprises third conductive pads; and
a functional chip, displayed on a side, facing away from the interposer, of the device substrate, wherein the functional chip is electrically connected to the third conductive pads.

10. The package structure according to claim 9, wherein the interposer further comprises fourth conductive pads, and the device substrate further comprises a first conductive pillars, wherein the first conductive pillars extends through the device substrate, and the fourth conductive pads are electrically connected to the first conductive pillars.

11. The package structure according to claim 10, further comprising: a second redistribution layer, wherein the second redistribution layer covers a surface, facing away from the interposer, of the device substrate and a surface of the silicon bridge, the functional chip is displayed on the second redistribution layer, and the second redistribution layer comprises a fifth conductive pads, one end of the fifth conductive pads being electrically connected to the third conductive pads, and the other end of the fifth conductive pads being electrically connected to the functional chip.

12. The package structure according to claim 11, wherein the second redistribution layer further comprises seventh conductive pads, wherein one end of the seventh conductive pads is electrically connected to the first conductive pillars, and the other end of the seventh conductive pads are electrically connected to the functional chip.

13. The package structure according to claim 9, further comprising: a package body, wherein the package body fills the recess.

14. The method according to claim 3, wherein upon forming the silicon bridge in the recess, the method further comprises: forming a second redistribution layer, wherein the second redistribution layer covers the surface, facing away from the interposer, of the device substrate and a surface of the silicon bridge, and the second redistribution layer comprises fifth conductive pads, the fifth conductive pads being electrically connected to the third conductive pads, and the fifth conductive pads being exposed on a surface of the second redistribution layer;
and wherein mounting the functional chip on the side, facing away from the interposer, of the device substrate comprises electrically connecting the functional chip to the fifth conductive pads.

15. The method according to claim 4, wherein upon forming the silicon bridge in the recess, the method further comprises: forming a second redistribution layer, wherein the second redistribution layer covers the surface, facing away from the interposer, of the device substrate and a surface of the silicon bridge, and the second redistribution layer comprises fifth conductive pads, the fifth conductive pads being electrically connected to the third conductive pads, and the fifth conductive pads being exposed on a surface of the second redistribution layer;
and wherein mounting the functional chip on the side, facing away from the interposer, of the device substrate comprises electrically connecting the functional chip to the fifth conductive pads.

16. The method according to claim 5, wherein upon forming the silicon bridge in the recess, the method further comprises: forming a second redistribution layer, wherein the second redistribution layer covers the surface, facing away from the interposer, of the device substrate and a surface of the silicon bridge, and the second redistribution layer comprises fifth conductive pads, the fifth conductive pads being electrically connected to the third conductive pads, and the fifth conductive pads being exposed on a surface of the second redistribution layer;
and wherein mounting the functional chip on the side, facing away from the interposer, of the device substrate comprises electrically connecting the functional chip to the fifth conductive pads.

17. The method according to claim 6, wherein upon forming the silicon bridge in the recess, the method further comprises: forming a second redistribution layer, wherein the second redistribution layer covers the surface, facing away from the interposer, of the device substrate and the surface of the silicon bridge, and the second redistribution layer comprises fifth conductive pads, the fifth conductive pads being electrically connected to the third conductive pads, and the fifth conductive pads being exposed on a surface of the second redistribution layer;
and wherein mounting the functional chip on the side, facing away from the interposer, of the device substrate comprises electrically connecting the functional chip to the fifth conductive pads.

18. The package structure according to claim 10, further comprising: a package body, wherein the package body fills the recess.

19. The package structure according to claim 11, further comprising: a package body, wherein the package body fills the recess.

20. The package structure according to claim 12, further comprising: a package body, wherein the package body fills the recess.
